(19) United States
(12) Patent Application Publication
(10) Pub. No.: US 2012/0126261 A1
(43) Pub. Date: May 24, 2012

(54) LENS, LIGHT-EMITTING MODULE, LIGHT-EMITTING ELEMENT PACKAGE, ILLUMINATION DEVICE, DISPLAY DEVICE, AND TELEVISION RECEIVER

(75) Inventor: Takaharu Shimizu, Osaka (JP)

(73) Assignee: SHARP KABUSHIKI KAISHA, Osaka (JP)

(21) Appl. No.: 13/388,280

(22) PCT Filed: Mar. 24, 2010
(86) PCT No.: PCT/JP2010/055039

§ 371 Date: Jan. 31, 2012

(30) Foreign Application Priority Data
Aug. 7, 2009 (JP) 2009-184496

(51) Int. Cl. H01L 33/58; F21V 5/04

(52) U.S. Cl. 257/88; 257/98; 362/326; 257/E33.06

(57) ABSTRACT

A lens (11) is bowl-shaped. The inner surface (11N) of the bowl shape is a housing recess (11N) which serves as a light receiving surface, and the outer surface (11S) of the bowl shape is a lens surface (11S) which serves as a light emission surface. The inner surface (11N) of the bowl shape is tapered toward the bottom of the bowl-shaped lens (11), and a conical, tip recess (12) which is receded from the outer surface (11S) is formed at the tapered end which is the bottom of the bowl-shaped lens (11).

### TECHNICAL FIELD

The present invention relates to a lens transmitting light, a light-emitting module including a lens, a light-emitting element package, an illumination device including a light-emitting module, a display device including an illumination device, and a television receiver equipped with a display device.

### BACKGROUND ART

A liquid crystal display device (display device) equipped with a non-light-emitting type liquid crystal display panel (display panel) usually includes a backlight unit (illumination device) for supplying light to the liquid crystal display panel. There are various kinds for a light source used in the backlight unit. For example, a light source used in the backlight unit described in Patent Document 1 is an LED (Light Emitting Diode).

The LED described in Patent Document 1 is mounted on a mounting substrate 121 as shown in a cross-sectional view in FIG. 17. A lens 111 is placed so as to cover a light emission surface of this LED 131. Further, a recess 112 in the shape of an inverse cone is formed near the top of a lens surface 111S of this lens 111. The surface of this recess 112 has an inclination angle of 55 to 85 degrees with respect to the vertical axis “cx” of the light emission surface of the LED 131.

When such a lens 111 is used, light that has relatively high light intensity and that is coming from the light emission surface of the LED 131 and traveling in the front direction, travels in the directions approximately 60 to 70 degrees inclined with respect to the vertical axis “cx” of the LED 131 (see θ in the figure). Accordingly, when each of a red light emitting LED 131, a green light emitting LED 131, and a blue light emitting LED 131 is covered by the lens 111, respectively, and those LEDs 131 are arranged at appropriate intervals, sufficient color mixing occurs and white light is generated.

### Related Art Documents

### Patent Documents

Patent Document 1: Japanese Patent Application Laid-Open Publication No. 2007-5791

### SUMMARY OF THE INVENTION

### Problems to be Solved by the Invention

However, the extent of the spread (extent of diffusion) of light from the LEDs 131 transmitting through the lenses 111 is not sufficient. Therefore, in order to suppress the color spattering phenomenon, a certain length becomes necessary in the front direction of the LEDs 131 (for example, as shown in FIG. 18, the distance “h” from the mounting substrate 121 to an optical sheet 146 becomes necessary).

As shown in FIG. 18, if the length in the front direction of the LEDs 131 becomes relatively long (see Paragraph 0046 of Patent Document 1), the thickness of the backlight unit and the liquid crystal display device becomes increased. Therefore, a thinner product, which is required for a display device of recent years, is not achieved.

The present invention was devised in order to solve the above-mentioned problem. An object of the present invention is to provide a lens and the like that are suited for attaining a thinner illumination device and display device.

### Means for Solving the Problems

A lens including a light emission surface has a first recess formed in the light emission surface, and an inner surface of the first recess, which receives light incident from a back surface of the light emission surface, has an inclination angle θ1 capable of totally reflecting light and guiding the light to the light emission surface. The inclination angle θ1 is defined by an angle formed by a central axis of the first recess in a conical shape and at least a part of an outer surface of the first recess, and the inclination angle θ1 satisfies Condition Formula (1) below.

15°≦θ1≦53° . . . Condition Formula (1)

With this structure, when light of the light-emitting element is supplied from the back surface of the lens, for example, the light is likely to be totally reflected by the first recess and to travel toward the light emission surface of the lens. Then, this light emission surface transmits or totally reflects the light according to its incident angle.

Then, the light traveling from the first recess is directly emitted from the light emission surface, or after the light is totally reflected by the light emission surface, it is totally reflected by another surface, and then comes back to the light emission surface again, then is emitted from the light emission surface. Accordingly, as compared to the light emitted from the first recess, a large part of the light emitted from this light emission surface does not travel in the front direction of the lens, but travels so as to spread radially away from the lens (that is, the light travels radially away from the lens), for example.

As a result, when a plurality of such lenses are arranged in a manner that light emitted from those lenses mix together, the distance in the front direction of the lenses required for mixing lights can be small. Accordingly, an illumination device in which the light-emitting elements are covered with such lenses and in which planar light is generated by mixing light emitted from the lenses becomes relatively thin, for example. Moreover, because lights are easily mixed together, the planar light is not likely to contain an unevenness in light amount. That is, it can be said that the above-mentioned lens is suited for attaining a thinner illumination device.

Furthermore, it is preferable that at least a part of the light emission surface have an inclination angle θ2 capable of totally reflecting light that is coming from an inner surface of the first recess after being totally reflected by the inner surface, and guiding that light to the back surface.

To explain in more detail, it is preferable that the inclination angle θ2 be defined by an angle formed by the inner surface of the first recess and an inner surface of the light emission surface facing each other, and that the inclination angle θ2 satisfy Condition Formula (2) below.

45°≦θ2≦135° . . . Condition Formula (2)

This is because when the inclination angle θ2 is outside the range of this Condition Formula (2), light emitted from the light emission surface of the lens may head toward the back surface side of the lens or may travel relatively along the central axis of the lens, making it difficult for the lens to emit diffused light.

Moreover, it is preferable that a second recess that is tapered toward the light emission surface be formed in the back surface of the lens. With this structure, light that was totally reflected by the light emission surface is likely to be totally reflected by the second recess on the way to the back surface of the lens. As a result, the incident angle with respect to the light emission surface is changed due to this second recess, and it becomes easier to generate emission light that spreads radially away from lens.

Specifically, if the second recess widens toward the back surface, emission light that spreads radially away from the lens is even more likely to be generated.

There is no special limitation for the material for the lens, but a material having the refractive index “Nd” of 1.49 or more and 1.6 or less is preferable.

Further, it is preferable that at least one of the bottom of the first recess of the lens and the connecting portion of the first recess and the light emission surface, which are the areas where light running through the inside of the lens is likely to be transmitted or reflected at, be in a curved surface shape.

With this structure, even when the light transmits through or is reflected by those sections, light does not travel isolatedly. Therefore, light emitted from an illumination device equipped with such a lens does not contain an unevenness in light amount, which is otherwise caused by light traveling isolatedly.

Moreover, the present invention encompasses a light-emitting module including the lens described above, a light-emitting element for supplying light to the lens, and a mounting substrate to which the lens and the light-emitting element are mounted. Furthermore, the present invention encompasses a light-emitting element package in which the above-mentioned lens and a light-emitting element for supplying light to the back surface of the lens are attached together, as well as a light-emitting module including a mounting substrate to which such a light element package is mounted.

It is preferable that, in such a light-emitting module, a diffusion reflective member be facing the back surface of the lens.

With this structure, light does not travel only in particular directions, but travels in various directions due to the diffusion reflective member. Therefore, the incident angle with respect to the light emission surface is changed, and it becomes easier to generate emission light that spreads radially away from the lens.

It is preferable that the diffusion reflective member be either a thin film formed on a mounting surface of the mounting substrate on which the light-emitting element is mounted, or a diffusion reflective sheet interposed between the back surface of the lens and the mounting surface of the mounting substrate.

The present invention encompasses an illumination device including the light-emitting module as well as a display device including such an illumination device and a display panel (liquid crystal display panel or the like) receiving light from the illumination device. Moreover, a television receiver including such an display device is also encompassed by the present invention.

### Effects of the Invention

The lens of the present invention is capable of emitting received light while diffusing it to the surroundings of the lens. Therefore, the distance in the front direction of the lenses required for mixing colors can be small in an illumination device in which these lenses are arranged, and a thin illumination device can be achieved.

### BRIEF DESCRIPTION OF THE DRAWINGS

FIG. 1 is a cross-sectional view showing a mounting substrate, an LED, and a lens.

FIG. 2 shows an example of the optical path of LED light traveling through the lens.

FIG. 3 shows an example of the optical path of LED light traveling through the lens.

FIG. 4 shows optical paths of light emitted from lenses mounted in a backlight unit.

FIG. 5 shows an example of the optical path of LED light traveling through a lens of a comparison example.

FIG. 6 shows an example of the optical path of LED light traveling through a lens of a comparison example.

FIG. 7 shows an example of the optical path of LED light traveling through a lens of a comparison example.

FIG. 8 shows an example of the optical path of LED light traveling through a lens of a comparison example.

FIG. 9 is a cross-sectional view showing a mounting substrate, an LED, and a lens.

FIG. 10 is a cross-sectional view showing a mounting substrate, an LED, and a lens.

FIG. 11 is a cross-sectional view showing a mounting substrate, an LED, and a lens.

FIG. 12 is a cross-sectional view showing a mounting substrate, an LED, a lens, and a diffusion reflective sheet.

FIG. 13 is an exploded perspective view of a liquid crystal display device.

FIG. 14 is a cross-sectional view of a backlight unit in a liquid crystal display device.

FIG. 15 is a graph in polar coordinates showing the directional characteristics of an LED.

FIG. 16 is an exploded perspective view of a television receiver.

FIG. 17 is a cross-sectional view showing a mounting substrate, an LED, and a lens mounted in a conventional backlight unit.

FIG. 18 shows optical paths of light emitted from lenses mounted in a conventional backlight unit.

### DETAILED DESCRIPTION OF EMBODIMENTS

### Embodiment 1

One embodiment of the present invention will be described below with reference to the figures. Here, hatchings, member characters and the like may be omitted for convenience, but in such cases, other figures should be referred to. A single-dot chain arrow line in the optical path views indicates light, and a black dot associated with arrow lines indicates the direction perpendicular to the plane of paper.

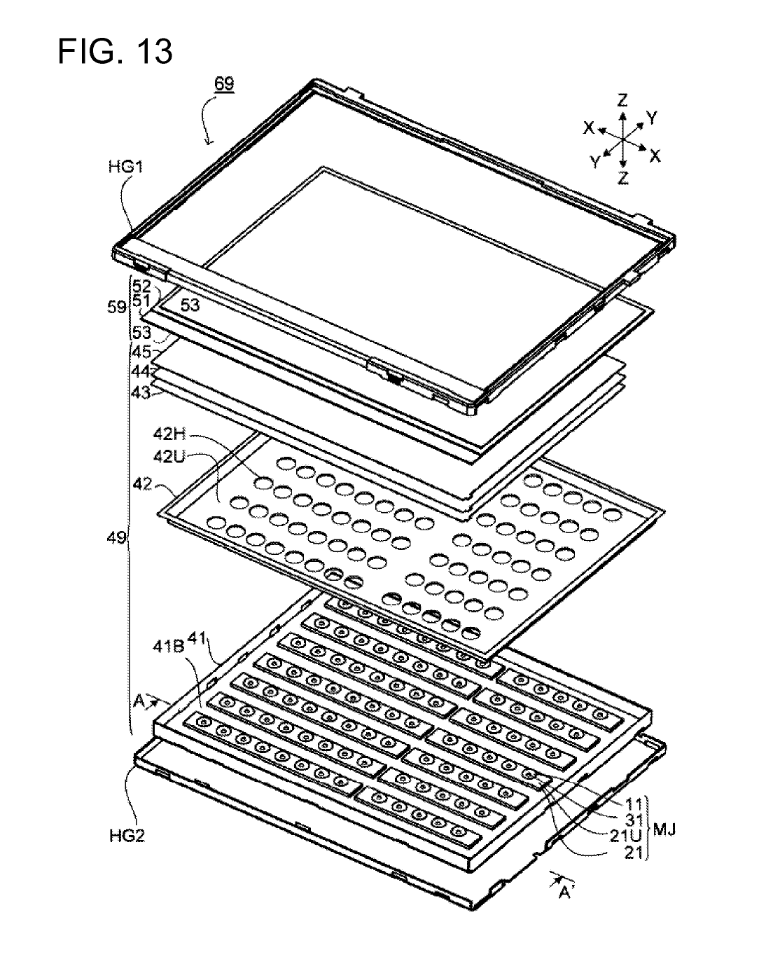

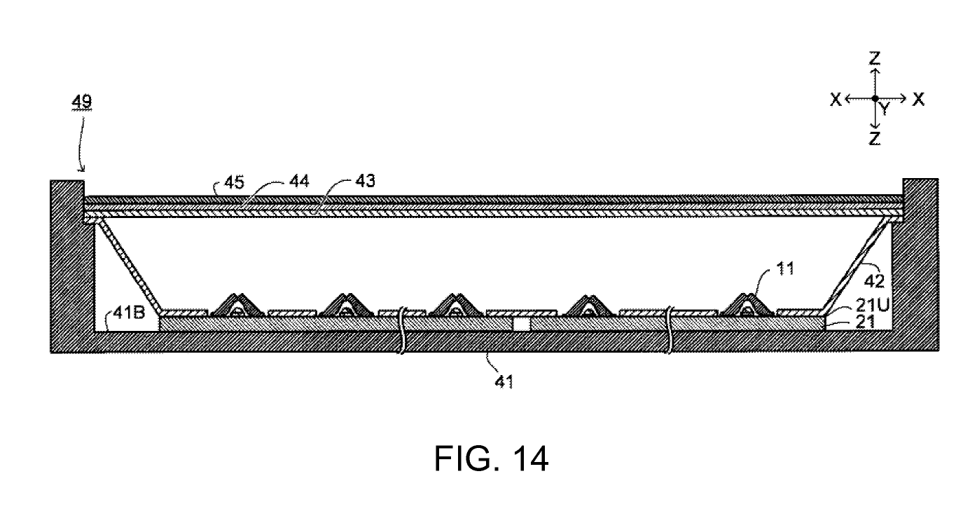

FIG. 16 is a liquid crystal television 89 equipped with a liquid crystal display device (display device) 69. The liquid crystal television 89 displays images by receiving television broadcasting signals, and therefore, it can be called a television receiver. FIG. 13 is an exploded perspective view showing the liquid crystal display device 69, and FIG. 14 is a cross-sectional view showing a backlight unit 49 included in the liquid crystal display device 69 (here, the cross-sectional direction is along the line A-A′ viewed in the arrow direction in FIG. 13).

As shown in FIG. 13, the liquid crystal display device 69 includes a liquid crystal display panel 59, the backlight unit (illumination device) 49 for supplying light to this liquid crystal display panel 59, and housings HG (front housing HG1 and back housing HG2) sandwiching these.

In the liquid crystal display panel 59, an active matrix substrate 51 including switching elements such as TFTs (Thin Film Transistors) or the like, and an opposite substrate 52 facing this active matrix substrate 51 are bonded together by a sealing member (not shown in the figure). Then, liquid crystal (not shown in the figure) is injected into a gap between the two substrates 51 and 52.

A polarizing film 53 is attached on a light-receiving surface side of the active matrix substrate 51 and on an emission surface side of the opposite substrate 52. The above-mentioned liquid crystal display panel 59 displays images using the change in transmittance caused by an inclination of liquid crystal molecules.

Next, the backlight unit 49 positioned straightly below the liquid crystal display panel 59 will be described. The backlight unit 49 includes LED modules (light-emitting modules) MJ, a backlight chassis 41, a large-sized reflective sheet 42, a diffusion plate 43, a prism sheet 44, and a micro lens sheet 45.

An LED module (light-emitting module) MJ includes a mounting substrate 21, LEDs (Light Emitting Diodes) 31, and lenses 11.

The mounting substrate 21 is a rectangular substrate, and on its mounting surface 21U, a plurality of electrodes (not shown in the figure) are disposed. On these electrodes, LEDs 31, which are light-emitting elements, are attached. Further, on the mounting surface 21U of the mounting substrate 21, a resist film (not shown in the figure), which is to be a protective film, is formed.

There is no special limitation for this resist film, but it is preferable that the color be white having reflectivity. This is because even if light impinges on the resist film, the light is reflected by the resist film and travels toward the outside, thereby eliminating a cause of an unevenness in light amount, which is light absorption by the mounting substrate 21.

The LED 31 is a light source, and emits light by a current through the electrodes on the mounting substrate 21. There are many different kinds for the LED 31, and LEDs 31 such as below are some examples. One example is an LED 31 including a blue light emitting LED chip (light-emitting chip) and a fluorescent member that emits yellow fluorescent light in response to light from the LED chip (here, there is no special limitation for the number of the LED chips). Such an LED 31 generates white light by light from the blue light emitting LED chip and the fluorescent light.

However, a fluorescent member built in an LED 31 is not limited to a fluorescent member that emits yellow fluorescent light. For example, an LED 31 may include a blue-light emitting LED chip and a fluorescent member that emits green and red fluorescent light in response to light from the LED chip, to generate white light by the blue light from the LED chip and the fluorescent light (green light and red light).

Moreover, an LED chip built in an LED 31 is not limited to an LED chip that emits blue light. For example, an LED 31 may include a red LED chip that emits red light, a blue LED chip that emits blue light, and a fluorescent member that emits green fluorescent light in response to light from the blue LED chip. Such an LED 31 can generate white light by red light from the red LED chip, blue light from the blue LED chip, and the green fluorescent light.

Further, an LED 31 including no fluorescent member may be used as well. For example, an LED 31 may include a red LED chip that emits red light, a green LED chip that emits green light, and a blue LED chip that emits blue light, to generate white light by light from all of the LED chips.

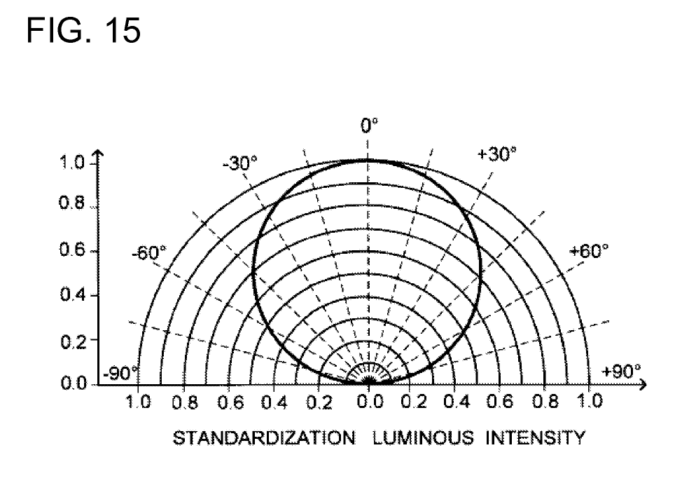

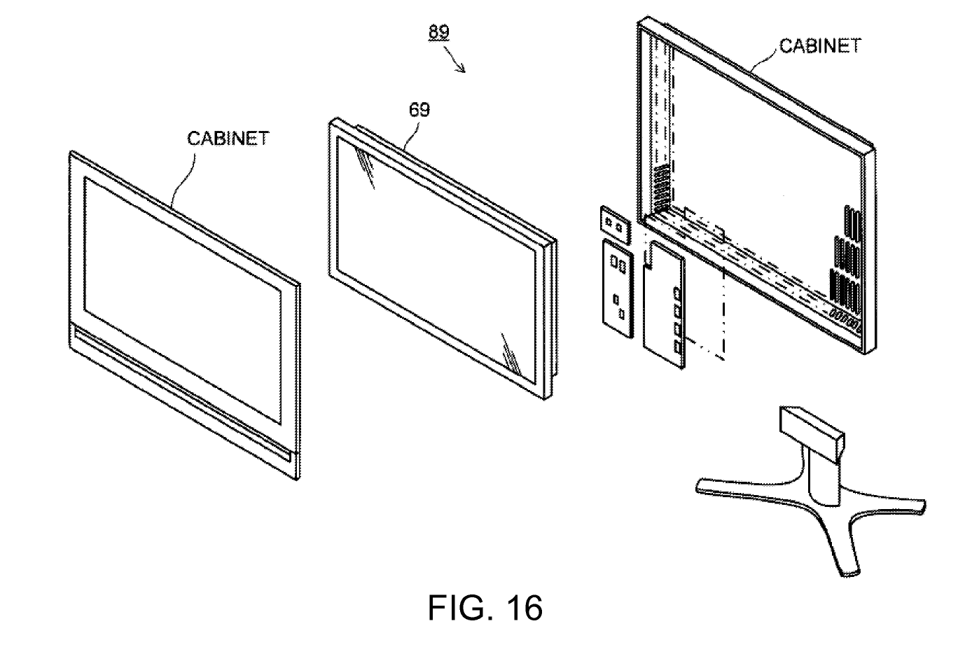

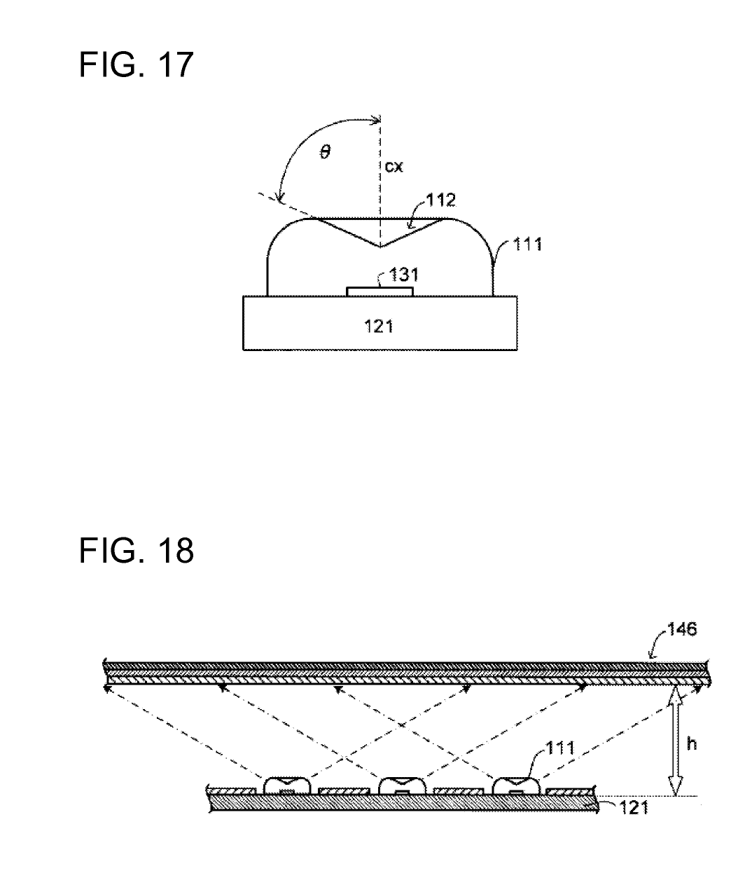

The directional characteristics of the LEDs 31 are represented in polar coordinates in FIG. 15 (here, the center of the polar coordinates indicates a light emitting point of an LED 31, and the vertical axis and the horizontal axis indicate the normalized light intensity in which the highest light intensity is normalized to 1.0). As shown in this figure, while an LED 31 has the highest light intensity in the front direction (that is, 0 degree) of the emission surface, the light intensity becomes lower as it moves closer to the horizontal directions (here, such distribution of light intensity can be called “Lambertian distribution”).

Mounted in the backlight unit 49 shown in FIG. 13 are a relatively short mounting substrate 21 where five LEDs 31 are aligned in a line on one mounting substrate 21, and a relatively long mounting substrate 21 where eight LEDs 31 are aligned in a line on one mounting substrate 21.

Specifically, the two kinds of mounting substrates 21 are arranged such that a line of five LEDs 31 and a line of eight LEDs 31 are aligned so as to become a line of thirteen LEDs 31, and further, the two kinds of mounting substrates 21 are also arranged in a direction crossing (such as perpendicular to) the direction in which the thirteen LEDs 31 are aligned. This way, the LEDs 31 are arranged in a matrix, and emit planar light (for convenience, the direction in which the different kinds of mounting substrates 21 are aligned is referred to as the X direction, the direction in which the same kind of mounting substrates 21 are aligned is referred to as the Y direction, and a direction crossing these X direction and Y direction is referred to as the Z direction).

Moreover, the thirteen LEDs 31 aligned in the X direction are electrically connected in series, and these thirteen LEDs 31 connected in series are further electrically connected in parallel to other thirteen LEDs 31, which are adjacent along the Y direction and connected in series. These LEDs 31 arranged in a matrix are driven parallelly.

The lens 11 is formed of Polymethyl Methacrylate (PMMA), Polycarbonate (PC) or the like having the refractive index “Nd” of approximately 1.49 or more and approximately 1.6 or less, and receives light from the LED 31 and transmits (emits) the light.

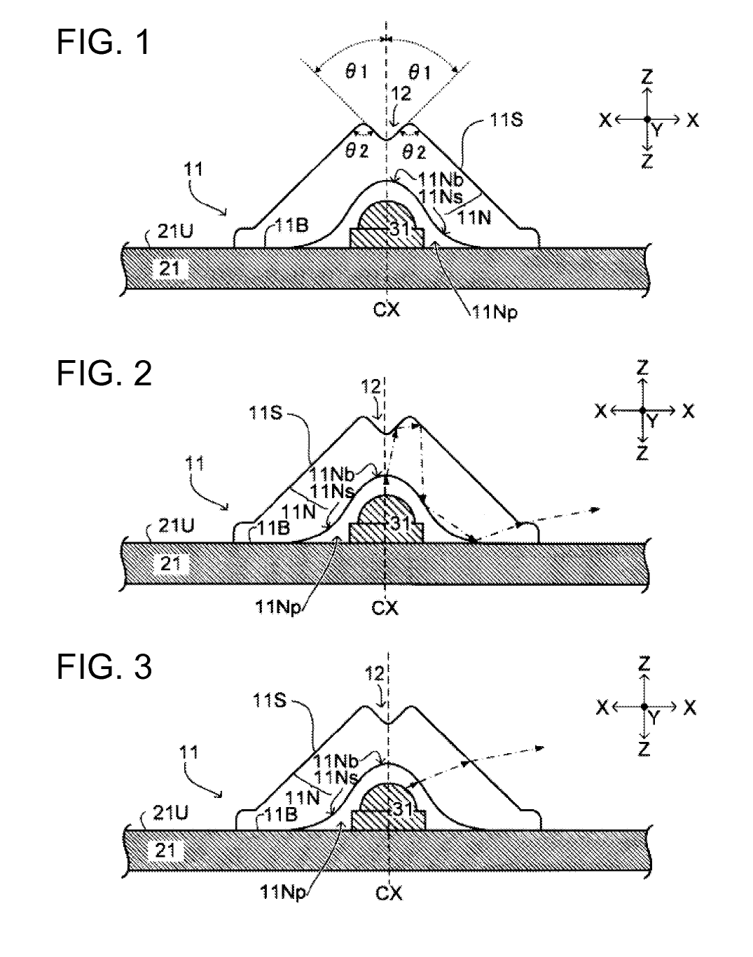

To explain in more detail, the lens 11 has a housing recess 11N that can house the LED 31 on a back surface (light-receiving surface) side of the lens surface 11S, and the lens 11 covers the LED 31 in a manner that the position of the housing recess 11N and that of the LED 31 correspond to each other (see FIG. 1, which will be described later). This way, the LED 31 is embedded inside the lens 11, and light from the LED 31 is supplied to the inside of the lens 11 with certainty. Then, a large part of the supplied light is emitted to the outside through the lens surface 11S. Further details of the lens 11 will be described later.

The backlight chassis 41 is a box-shaped member as shown in FIG. 13, for example, and contains a plurality of the LED modules MJ by arranging the LED modules MJ on a bottom surface 41B. Here, the bottom surface 41B of the backlight chassis 41 and the mounting substrates 21 of the LED modules MJ are connected to each other by rivets (not shown in the figure), for example.

The large-sized reflective sheet 42 is an optical member having a reflective surface 42U, and covers the plurality of LED modules MJ, which are arranged in a matrix, such that a back surface of the reflective surface 42U faces the LED modules MJ. Here, the large-sized reflective sheet 42 has passage holes 42H, which correspond to the position of the lenses 11 of the LED modules MJ to expose the lenses 11 from the reflective surface 42U.

Therefore, even if a part of the light emitted from the lenses 11 travels toward the bottom surface 41B side of the backlight chassis 41, the light is reflected by the reflective surface 42U of the large-sized reflective sheet 42 and travels away from the bottom surface 41B. Accordingly, due to the large-sized reflective sheet 42, light from the LEDs 31 travels toward the diffusion plate 43, which faces the reflective surface 42U, without causing light loss.

The diffusion plate 43 is a plate-like optical member that overlaps with the large-sized reflective sheet 42, and diffuses light emitted from the LED modules MJ and the reflected light coming from the large-sized reflective sheet 42U. In other words, the diffusion plate 43 diffuses planar light formed by the plurality of LED modules MJ, and spreads the light to the entire region of the liquid crystal display panel 59.

The prism sheet 44 is a sheet-like optical member overlapping the diffusion plate 43. In this prism sheet 44, triangle prisms extending in one direction (in a linear shape), for example, are aligned in a direction perpendicular to that one direction on the sheet surface. This way, the prism sheet 44 changes directional properties in the radiation characteristics of light from the diffusion plate 43. Here, it is preferable that the prisms extend along the Y direction in which less LEDs 31 are aligned, and be aligned along the X direction in which more LEDs 31 are aligned.

The micro lens sheet 45 is a sheet-like optical member overlapping the prism sheet 44. This micro lens sheet 45 has particles dispersed inside thereof for light refraction and scattering. Accordingly, the micro lens sheet 45 suppresses the difference in luminance (unevenness in light amount) without locally concentrating light from the prism sheet 44.

The above-mentioned backlight unit 49 transmits planar light, which is formed by the plurality of LED modules MJ, through the plurality of optical members 43 to 45, and supplies the light to the liquid crystal display panel 59. Accordingly, the non-light-emitting type liquid crystal display panel 59 receives light (backlight light) from the backlight unit 49 to improve the display function.

Here, the lens 11 will be described in detail with reference to FIGS. 1 to 8. As shown in the partial cross-sectional view of FIG. 1, the lens 11 is bowl-shaped, and the inner surface 11N of the bowl shape covers the LED 31. To explain in more detail, the lens 11 is configured such that the inner surface 11N of the bowl shape defines a housing recess 11N for housing the LED 31, and the outer surface 11S of the bowl shape is a lens surface 11S that serves as a light emission surface.

The bowl-shaped inner surface 11N (that is, the housing recess 11N), which serves as a light receiving surface, is tapered toward the bottom of the bowl-shaped lens 11, and a conical, tip recess 12, which is receded from the outer surface 11S (that is, the lens surface 11S), is formed (carved) at the tapered end, which is the bottom of the bowl-shaped lens 11.

In order to house the LED 31, the housing recess (second recess) 11N has an entrance 11Np that is larger than the shape of the LED 31 of the lens 11, and has a shape tapered from the entrance 11Np toward the bottom of the bowl-shaped lens 11, or a shape similar to a circular cone, for example (here, the depth of the housing recess 11N is deeper than the height of the LED 31).

An axis that overlaps with the tip of such a tapered housing recess 11N (that is, the bottom of the housing recess 11N), and that overlaps with the in-plane center of the entrance 11Np is referred to as a central axis “CX.” Thus, when the housing recess 11N of the lens 11 covers the LED 31 on the mounting substrate 21, the central axis CX overlaps with the LED 31 (an in-plane center of the emission surface of the LED 31, for example). When the housing recess 11N covers the LED 31 in such a manner, the housing recess 11N and the LED 31 do not contact each other.

The surface of the housing recess 11N includes a bottom surface section 11Nb, which is the bottom of the housing recess 11N overlapping with the central axis “CX”, and a side surface section 11Ns, which is an area other than the bottom of the housing recess 11N and which corresponds to the side surface. As for the surface shape of the bottom surface section 11Nb, the center of curvature is positioned at the housing recess 11N side, and as for the surface shape of the side surface section 11Ns, the center of curvature is positioned at the lens surface 11S side. Further, the radius of curvature of the bottom surface section 11Nb is smaller than the radius of curvature of the side surface section 11Ns (that is, the curvature of the surface shape of the bottom surface section 11Nb is greater than the curvature of the surface shape of the side surface section 11Ns).

As a result, the surface shape of the housing recess 11N becomes a surface shape similar to the inner surface of a trumpet bell. In other words, the surface shape of the housing recess 11N is tapered toward the bottom of the bowl-shaped lens 11, and widens toward the entrance 11Np of the bowl (specifically, from the entrance 11Np of the housing recess 11N to the bottom surface section 11Nb, a series of the surface tops of the side surface section 11Ns forms the constricted section of the housing recess 11N).

Meanwhile, the tip recess (first recess) 12 is carved from the tapered edge section, which is the bottom of the bowl shape, or in other words, from the top of the lens surface 11S of the bowl-shaped lens 11. This tip recess 12 has a tapered shape, that is, a conical shape similar to a circular cone, for example.

When light of the LED 31 is transmitted through the above-mentioned lens 11 that includes the housing recess 11N and the tip recess 12, an optical path shown in FIG. 2 appears, for example.

To explain in more detail, a large part of the light that traveled from the emission surface of the LED 31 and reached the bottom surface section 11Nb is refracted by the bottom surface section 11Nb, and enters the inside of the lens 11 (here, light with relatively high light intensity enters the bottom surface section 11Nb, which is located almost straightly above the LED 31; see FIG. 15).

This light reaching the bottom surface section 11Nb does not have an excessive inclination angle with respect to the central axis CX of the housing recess 11N. Therefore, a large part of the light entering the inside of the lens 11 is not refracted excessively by the bottom surface section 11Nb, and reaches the tip recess 12 that is located in the vicinity of an area straightly above the bottom surface section 11Nb.

The surface of the tip recess 12 is a recessed surface (pyramidal surface) tapered from the top of the surface of the lens surface 11S. Therefore, the inner surface of the tip recess 12 (surface of the tip recess 12 inside of the lens 11) forms an obtuse angle with respect to the central axis CX. Accordingly, when light that reached the inner surface of the tip recess 12 is totally reflected, the light is likely to head toward the lens surface 11S.

The inner surface of the lens surface 11S (lens surface 11S inside of the lens 11) where light totally reflected by the inner surface of the tip recess 12 reaches intersects with the inner surface of the tip recess 12. Therefore, when light that reached the inner surface of the lens surface 11S is totally reflected, it would be likely to travel so as to return to the housing recess 11N.

When the light travels so as to return to the housing recess 11N, the light is coming from the lens surface 11S that is located further away from the central axis CX relative to the inner surface of the tip recess 12. Therefore, the light is likely to reach the side surface section 11Ns that is further away from the central axis CX relative to the bottom surface section 11Nb of the housing recess 11N.

The housing recess 11N including the side surface section 11Ns has a tapered shape similar to the shape of the lens 11, and therefore, the side surface section 11Ns facing the lens surface 11S is also inclined similarly to the lens surface 11S. As a result, light that is traveling from the lens surface 11S toward the housing recess 11N in a direction further away from the total reflection point of the lens surface 11S is likely to be totally reflected by the side surface section 11Ns; further travels toward the periphery of the lens 11; and then is likely to be totally reflected again at the side surface section 11Ns (that is, at the side surface section 11Ns close to the mounting surface 21U).

As shown in FIG. 2, this totally reflected light reaches the lens surface 11S without traveling excessively away from an in-plane direction of the mounting surface 21U. As a result, the incident angle of the light with respect to the lens surface 11S is likely to become smaller than the critical angle, and therefore, the light is likely to be emitted toward the outside. That is, light that travels in the lens 11 in the direction within the plane of the mounting surface 21U is emitted from the periphery of the lens surface 11S toward the diffusion plate 43 while traveling away from the housing recess 11N. Therefore, the light emitted from the lens surface 11S is diffused radially away from the lens 11.

Meanwhile, as shown in FIG. 3, some of the light from the emission surface of the LED 31 impinges on the side surface section 11Ns of the housing recess 11N instead of the bottom surface section 11Nb (here, the light intensity of such light is lower than the light intensity of the front direction of the LED 31). Such light is refracted by the side surface section 11Ns and enters the inside of the lens 11, but is likely to travel in a direction away from the tip recess 12 toward the facing lens surface 11S.

This light heading toward the lens surface 11S enters the lens surface 11S at an incident angle smaller than that of the light heading toward the lens surface 11S after traveling through the inner surface of the tip recess 12. Therefore, the light is emitted to the outside without being totally reflected by the lens surface 11S (that is, the light is emitted to the outside with the minimum number of refraction). This emitted light has a relatively large emission angle with respect to the normal direction of the lens surface 11S according to Snell's law, and therefore, the light travels away from the tip recess 12 while heading toward the diffusion plate 43. Accordingly, this emission light is also diffused radially away from the lens 11.

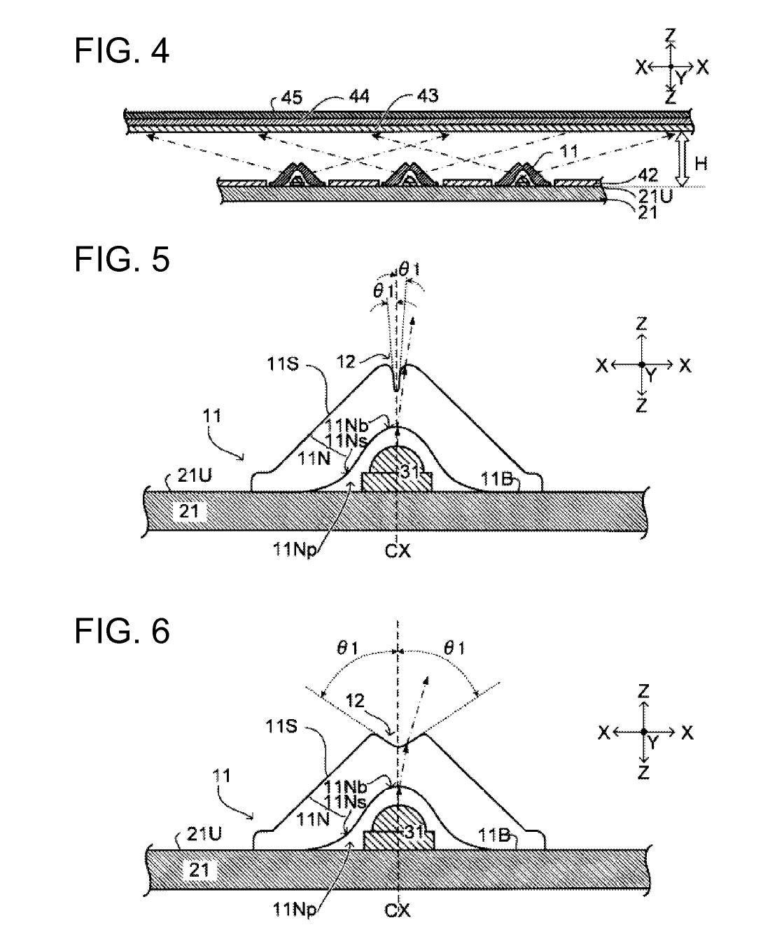

In other words, in light of the optical path views of FIGS. 2 and 3, the lens 11 can be called a diffusion lens that emits light while diffusing it radially away from the lens (that is, light emitted from the lens 11 travels radially away from the lens 11 while keeping the elevation angle relatively small). When such a lens 11 is used, as shown in FIG. 4, even when the distance H between the bottom surface 41B of the backlight chassis 41 and the diffusion plate 43 becomes relatively small (that is, even when the thickness of the backlight unit 49 becomes small), for example, light emitted from a plurality of the lenses 11 becomes overlapped with each other in reaching the diffusion plate 43.

Thus, when a plurality of such lenses 11 are arranged such that light emitted from those lenses 11 is mixed together, the distance in the front direction of the lens 11 required for color mixture can be small. Therefore, the backlight unit 49 in which the LEDs 31 are covered with such lenses 11 and in which planar light is generated by mixing light emitted from the lenses 11, for example, becomes relatively thin.

Moreover, such a backlight unit 49 can avoid a situation like where light emitted from a plurality of the lenses 11 is not overlapped with each other in reaching the diffusion plate 43, and the diffusion plate 43 ends up including a mixture of a region where the emission light is reflected and a region where the emission light does not reach, resulting in light transmitting through the diffusion plate 43 and the like (backlight light) that contains an unevenness in light amount.

Further, the overlapped lights reach the diffusion plate 43 even though the LEDs 31 slightly differ from one another in their light intensities due to the variations in them, and therefore, it becomes unlikely for the backlight light transmitting through the diffusion plate 43 and the like to contain an unevenness in light amount due to each LED 31 having a different light intensity.

Here, as shown in FIG. 2, the inner surface of the tip recess 12, which receives light entering from the bottom of the housing recess 11N, that is, the inner surface 11N of the lens 11, is inclined such that it can totally reflect the light and guide the light to the lens surface 11S, that is, the outer surface 11S of the lens 11, but there is a preferable range for the angle (inclination angle θ1). It is a range satisfying Condition Formula (1) below.

15°≦θ1≦53° . . . Condition Formula (1)

Where, “θ1” is the angle formed by the central axis CX of the conical tip recess 12 and the pyramidal surface of the tip recess 12 (to explain in more detail, the outer surface of the tip recess 12 contacting the outside).

For example, when “θ1” is smaller than the minimum value of Condition Formula (1), the skirt of the conical tip recess 12 becomes small, and a considerably long and thin tip recess 12 is obtained, as shown in FIG. 5. Accordingly, the surface of the tip recess 12 is inclined along the central axis CX, thereby making it difficult for the surface of the tip recess 12 to receive light traveling in the front direction of the LED 31. Thus, as shown in FIG. 5, light traveling in the front direction of the LED 31 directly reaches the lens surface 11S without reaching the tip recess 12.

In such a case, the incident angle of light with respect to the lens surface 11S is relatively small, and therefore, the light transmits through the lens surface 11S and is emitted to the outside without being totally reflected. Moreover, although an emission angle of the emitted light becomes larger than the incident angle, the incident angle is small, and therefore, the emission angle does not become so large. Accordingly, it is difficult for such a lens 11 to cause light from the lens surface 11S to travel significantly away from the central axis CX of the lens 11 to diffuse the light.

On the other hand, when “θ1” is larger than the maximum value of Condition Formula (1), the skirt of the tip recess 12 becomes large, and the tip recess 12 having a relatively small depth is obtained, as shown in FIG. 6. Accordingly, the surface of the tip recess 12 is inclined so as to move away from the central axis CX, and is likely to receive light traveling in the front direction of the LED 31. Thus, as shown in FIG. 6, light traveling in the front direction of the LED 31 directly reaches the inner surface of the tip recess 12.

In such a case, the incident angle of light with respect to the inner surface of the tip recess 12 becomes smaller than the incident angle of light with respect to the inner surface of the tip recess 12 shown in FIG. 2, and therefore, the light is likely to transmit through the inner surface of the tip recess 12 to the outside without being totally reflected. Moreover, because the inner surface of the tip recess 12 and the lens surface 11S, which are connected to each other at the skirt of the tip recess 12 as a border, are crossing to each other, it is difficult for light emitted from the inner surface of the tip recess 12 to travel away from the central axis CX as compared to the light emitted from the lens surface 11S. As a result, it is difficult for such a lens 11 to cause light emitted from the inner surface of the tip recess 12 to travel significantly away from the central axis CX of the lens 11 to diffuse the light.

However, when “θ1” is within the range of Condition Formula (1), as shown in FIG. 2, a large part of the light in the front direction of the LED 31 enters the inside of the lens 11 through the housing recess 11N; and after the light is totally reflected by the inner surface of the tip recess 12, the light is totally reflected by the lens surface 11S as well; and then returns to the housing recess 11N. Further, this light is likely to be reflected multiple times or a single time at the side surface section 11Ns of the tapered housing recess 11N; travels toward the lens surface 11S away from the central axis CX; and exits to the outside from the lens surface 11S.

Therefore, light emitted from this lens surface 11S is diffused radially away from the lens 11 (i.e., from the central axis CX). In other words, unlike the lenses 11 shown in FIGS. 5 and 6, the lens 11 shown in FIG. 2 can effectively diffuse light in the front direction of the LED 31 having the highest light intensity. Accordingly, the backlight unit 49 equipped with such a lens 11 generates backlight light with even more suppressed unevenness in light amount while being thin.

Here, the lens surface 11S is inclined such that it can further totally reflect light that has been totally reflected by the inner surface of the tip recess 12, and guide the light to the housing recess 11N (ideally, the side surface section 11Ns), but there is a preferable range for the angle (inclination angle θ2). It is a range satisfying Condition Formula (2) below.

45°≦θ2≦135° . . . Condition Formula (2)

Here, “θ2” is the angle formed by the inner surface of the tip recess 12 and the inner surface of the lens surface 11S facing each other.

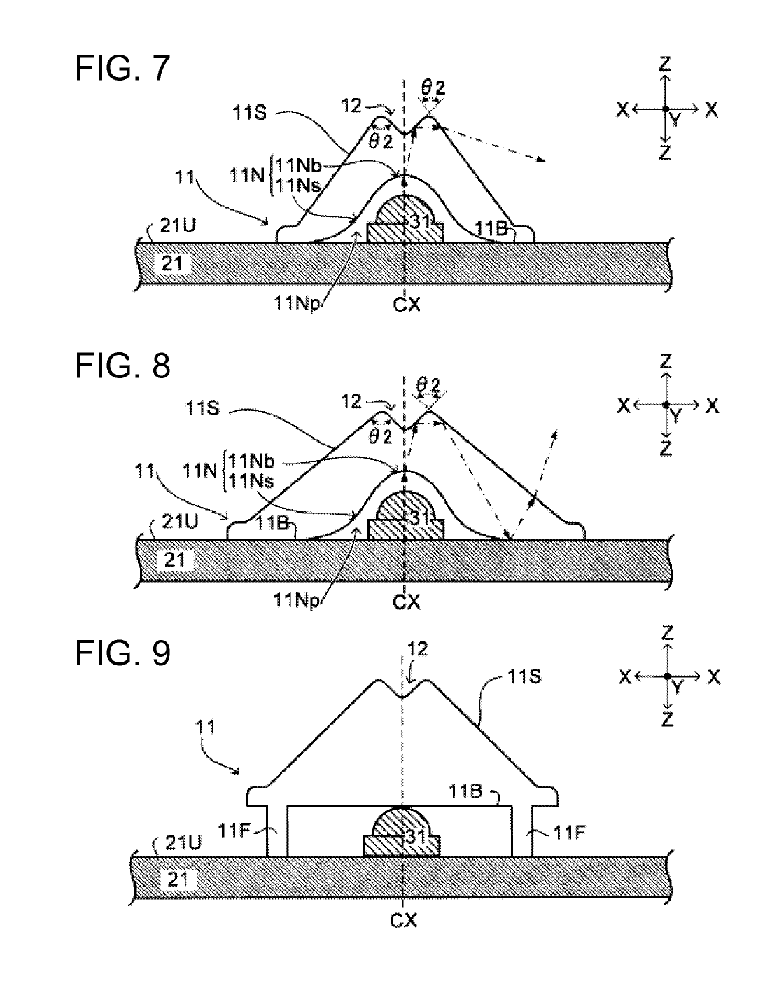

For example, when “θ2” is smaller than the minimum value of Condition Formula (2), the incident angle of light totally reflected by the inner surface of the tip recess 12 and that reaches the lens surface 11S is likely to become relatively small, as shown in FIG. 7. Therefore, the light is likely to transmit through the lens surface 11S and is emitted to the outside without being totally reflected at the lens surface 11S. Moreover, when light coming from the inner surface of the tip recess 12 is traveling in the substantially horizontal direction, the resultant light emitted to the outside is likely to travel toward the back surface side of the lens 11 (that is, the mounting substrate 21).

Therefore, it is difficult for such a lens 11 to mix light coming from the lens surface 11S with lights from other lenses 11. Accordingly, the backlight light may possibly contain an unevenness in light amount due to the fact that light emitted from a plurality of the lenses 11 do not overlap with each other.

On the other hand, when “θ2” is larger than the maximum value of Condition Formula (2), as shown in FIG. 8, the incident angle of light totally reflected by the inner surface of the tip recess 12 and that reaches the lens surface 11S is likely to become larger than the incident angle with respect to the lens surface 11S shown in FIG. 2. Therefore, a total reflection is likely to occur at the lens surface 11S. However, the refraction angle of the totally reflected light is relatively large, and the light is likely to reach the back surface of the lens 11 facing the mounting surface 21U, not the housing recess 11N.

Moreover, when a total reflection occurs at the back surface of the lens 11, and the totally reflected light transmits through the lens surface 11S to the outside, because the lens surface 11S (to explain in detail, the inner surface of the lens surface 11S) has an inclination relatively closer to the mounting surface 21U, the emission light is unlikely to travel away from the central axis CX. Therefore, it is difficult for such a lens 11 to cause the light from the lens surface 11S to travel significantly away from the central axis CX of the lens 11, and the backlight light may possibly contain an unevenness in light amount. Further, the light totally reflected by the lens surface 11S may transmit through the back surface of the lens 11 and be absorbed by the mounting surface 21U, possibly causing light quantity loss.

However, when “θ2” is within the range of Condition Formula (2), as shown in FIG. 2, light emitted from the lens 11 is diffused radially away from the lens 11 (i.e., from the central axis CX). Accordingly, the backlight unit 49 equipped with such a lens 11 generates backlight light with even more suppressed unevenness in light amount while being thin.

### Other Embodiments

Furthermore, the present invention is not limited to the above-mentioned Embodiment, and various modifications are possible without departing from the scope of the present invention.

For example, the housing recess 11N was formed in the back surface 11B of the lens 11 in the foregoing, but there is no limitation to this. That is, as shown in FIG. 9, the lens 11 may include no housing recess 11N and may receive light from the LED 31 on its back surface 11B (here, leg members 11F for attaching the lens 11 to the mounting substrate 21 are formed on the back surface 11B of the lens 11).

Even when such a lens 11 is used, light of the LED 31 supplied from the back surface 11B of the lens 11 is likely to be totally reflected by the tip recess 12 and to head toward the lens surface 11S, and this lens surface 11S transmits or totally reflects the light according to its incident angle. Then, the light traveling from the tip recess 12 is directly emitted from the lens surface 11S; or after the light is totally reflected by the lens surface 11S, it is totally reflected by another surface (back surface 11B, for example), and then comes back to the lens surface 11S again, then is emitted from the lens surface 11S.

Accordingly, a large part of the light emitted from this lens surface 11S does not travel in the front direction of the lens 11, and spreads radially away from the lens 11 as compared to the light emitted from the tip recess 12, for example. In other words, the functions and effects similar to the lens 11 described above are obtained.

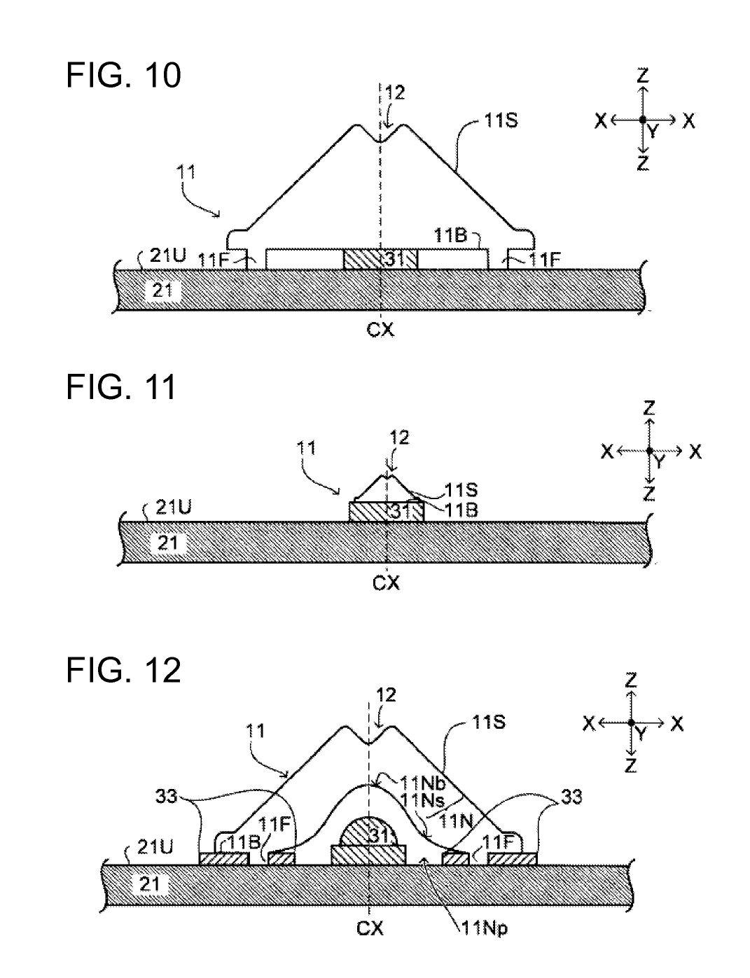

Moreover, a hemispherical tip lens was attached to the tip of the LED 31 described above, but instead of this tip lens, the lens 11 described above may be attached in a manner shown in FIG. 10. That is, the emission surface of the LED 31 may be directly attached to the back surface 11B of the lens 11 in the area straightly below the tip recess 12.

Furthermore, as shown in FIG. 11, the lens 11 shown in FIG. 10 may be made small in size similar to the tip lens (here, as shown in FIGS. 10 and 11, a combination of the LED 31 and the lens 11 directly attached together is referred to as an LED package (light-emitting element package)).

The housing recess 11N, which is tapered toward the lens surface 11S, is formed in the back surface 11B of the lens 11 shown in FIG. 1 and other figures, and because of this housing recess 11N, light totally reflected by the lens surface 11S is likely to be totally reflected by the housing recess 11N on the way to the back surface 11B of the lens 11. Accordingly, the incident angle with respect to the lens surface 11S is changed due to the housing recess 11N, and it becomes easier to generate emission light that spreads radially away from the lens 11.

Specifically, if the housing recess 11N widens toward the back surface 11B of the lens 11, emission light that spreads radially away from the lens 11 as shown in FIG. 2 is even more likely to be generated.

Moreover, it is preferable that at least one of the bottom of the tip recess 12 and the connecting portion of the tip recess 12 and the lens surface 11S (that is, the skirt of the top recess 12), which are the areas where light running through the inside of the lens 11 is likely to be transmitted through or reflected at, be in a curved surface shape (R shape).

If these areas are configured to be edges having an angle, when light inside the lens 11 reaches those areas, the light is likely to travel isolatedly in multiple directions, and is likely to become a cause for an unevenness in light amount in the backlight light. However, if those areas are configured to have a curved shape, light does not travel isolatedly. As a result, the backlight light is not likely to contain the unevenness in light mount.

The areas to become an R-shape are not limited to the bottom of the tip recess 12 and the connecting portion of the tip recess 12 and the lens surface 11S, and all of the edged sections of the lens 11 may be in an R-shape.

Moreover, as shown in FIG. 12, it is preferable that a diffusion reflective sheet (diffusion reflective member) 33 be interposed between the back surface 11B of the lens 11 and the mounting surface 21U of the mounting substrate 21. With this structure, light inside the lens 11 does not travel only in particular directions, but travels in various directions by being reflected by the diffusion reflective sheet 33. Therefore, the incident angle with respect to the lens surface 11S is changed, and it becomes easier to generate emission light that spreads radially away from the lens 11. Further, the diffusion reflective sheet 33 may also be interposed between the back surface 11B of the lens 11 and the mounting surface 21U shown in FIG. 10.

Moreover, if the resist film (diffusion reflective member) on the mounting surface 21U has diffusion reflectivity, the resist film may perform a role similar to the diffusion reflective sheet 33 in place of the diffusion reflective sheet 33 (that is, it is preferable that the diffusion reflective sheet 33 or the resist film face the back surface 11B of the lens 11).

Moreover, it is not necessary for the entire surface of the tip recess 12 to satisfy the above-mentioned Condition Formula (1). In other words, at least a part of the surface of the tip recess 12 needs to satisfy the above-mentioned Condition Formula (1). This is because if at least a part of the surface of the tip recess 12 satisfies Condition Formula (1), it is possible to make light from the lens surface 11S travel significantly away from the central axis CX of the lens 11 as compared to the lens 11 including the tip recess 12 that does not satisfy Condition Formula (1) at all.

Furthermore, the entire lens surface 11S does not need to satisfy the above-mentioned Condition Formula (2). In other words, at least a part of the lens surface 11S needs to satisfy the above-mentioned Condition Formula (2). This is because if at least a part of the lens surface 11S satisfies Condition Formula (2), it is possible to make light from the lens surface 11S travel significantly away from the central axis CX of the lens 11 as compared to the lens 11 including the lens surface 11S that does not satisfy Condition Formula (2) at all.

### DESCRIPTION OF REFERENCE CHARACTERS

11 Lens

11S Lens surface (outer surface of lens)

11B Back surface of lens

11N Housing recess (inner surface of lens, second recess)

11Nb Bottom surface section of housing recess

11Ns Side surface section of housing recess

12 Tip recess (first recess)

21 Mounting substrate

21U Mounting surface

31 LED (light-emitting element, point-like light source)

33 Diffusion reflective sheet (diffusion reflective member)

MJ LED module (light-emitting module)

41 Backlight chassis

41B Bottom surface of backlight chassis

42 Large reflective sheet

43 Diffusion plate

44 Prism sheet

45 Micro lens sheet

49 Backlight unit

59 Liquid crystal display panel (display panel)

69 Liquid crystal display device (display device)

89 Television receiver

1. A lens comprising a light emission surface,
wherein a first recess is formed in said light emission surface,
wherein an inner surface of said first recess, which receives light incident from a back surface of said light emission surface, has an inclination angle θ1 capable of totally reflecting light and guiding the light to said light emission surface, and
wherein said inclination angle θ1 is defined by an angle formed by a central axis of said first recess in a conical shape and at least a part of an outer surface of said first recess, and the inclination angle θ1 satisfies Condition Formula (1) below.
15°≦θ1≦53° . . . Condition Formula (1)

2. The lens according to claim 1,
wherein at least a part of said light emission surface has an inclination angle θ2 capable of totally reflecting light that is coming from an inner surface of said first recess after being totally reflected by the inner surface, and guiding the light to said back surface.

3. The lens according to claim 2,
wherein said inclination angle θ2 is defined by an angle formed by the inner surface of said first recess and an inner surface of said light emission surface facing each other, and the inclination angle θ2 satisfies Condition Formula (2) below.
45°≦θ2≦135° . . . Condition Formula (2)

4. The lens according to claim 1,
wherein a second recess that is tapered toward said light emission surface is formed in said back surface.

5. The lens according to claim 4, wherein said second recess widens toward said back surface.

6. The lens according to claim 1, formed of a material having a refractive index Nd of 1.49 or more and 1.6 or less.

7. The lens according to claim 1, wherein at least one of a bottom of said first recess and a portion connecting said first recess to said light emission surface is in a curved shape.

8. A light-emitting module, comprising:
the lens according to claim 1;
a light-emitting element for supplying light to said lens; and
a mounting substrate to which said lens and said light-emitting element are attached.

9. A light-emitting element package, comprising:
the lens according to claim 1; and
a light-emitting element directly attached to said lens for supplying light to a back surface of said lens.

10. A light-emitting module, comprising a mounting substrate to which the light-emitting element package according to claim 9 is attached.

11. The light-emitting module according to claim 8, further comprising a diffusion reflective member that faces a back surface of said lens.

12. The light-emitting module according to claim 11, wherein said diffusion reflective member is one of a thin film formed on a mounting surface of said mounting substrate on which said light-emitting element is mounted, and a diffusion reflective sheet interposed between said back surface and said mounting surface.

13. An illumination device, comprising the light-emitting module according to claim 8.

14. A display device comprising:
the illumination device according to claim 13; and
a display panel that receives light from said illumination device.

15. The display device according to claim 14, wherein said display panel is a liquid crystal display panel.

16. A television receiver equipped with the display device according to claim 14.
